(19) United States
(12) Patent Application Publication
(10) Pub. No.: US 2026/0068124 A1
(43) Pub. Date: Mar. 5, 2026

(54) VERTICAL FIN-GATE TRANSISTOR AND MEMORY DEVICE

(71) Applicant: NANYA TECHNOLOGY CORPORATION, New Taipei City (TW)

(72) Inventor: Wen Kuei HUANG, New Taipei City (TW)

(21) Appl. No.: 18/823,696

(22) Filed: Sep. 4, 2024

(51) Int. Cl. H10B 12/00

(52) U.S. Cl. CPC H10B 12/315

(57) ABSTRACT

Embodiments of the present disclosure provide a memory device and a vertical fin-gate transistor. The memory device includes a memory cell including a bit line, a word line above the bit line, and a semiconductor substrate on the bit line. The word line includes a plurality of fin type word lines, a fin connector connecting the fin type word lines, and a common word line on the fin connector. The memory cell also includes a body line physically contacting one of sidewalls of the semiconductor substrate and an insulating layer embedding the body line, where the fin type word lines partially cover others of the sidewalls of the semiconductor substrate. The body line is grounded to direct the accumulated charges out of the semiconductor substrate, thereby reducing the floating body effect in the memory cell.

### BACKGROUND

### Field of Invention

The present invention relates to the memory device. More particularly, the present invention relates to the memory device including the vertical fin-gate transistor.

### Description of Related Art

Surrounding gate transistor (SGT) is one of the candidates for dynamic random access memory (DRAM) design. Generally, a surrounding gate transistor includes a channel in a pillar structure and a gate surrounding the channel with source/drain regions at the top and the bottom of the pillar structure. However, the charges can be accumulated in the pillar structure, which leads to the floating body effect of the surrounding gate transistor.

### SUMMARY

According to some embodiments of the present disclosure, a vertical fin-gate transistor includes a bit line, a word line above the bit line, and a semiconductor substrate on the bit line. The word line includes a fin type word line, a fin connector on a top surface of the fin type word line, and a common word line on a top surface of the fin connector. The semiconductor substrate includes a channel region covered by the fin type word line, a top source/drain region on a top surface of the channel region, and a bottom source/drain region below a bottom surface of the channel region, where a ratio of widths of sidewalls of the semiconductor substrate is in a range of 0.5:1 to 1.5:1. The vertical fin-gate transistor also includes a body line physically contacting a first sidewall of the channel region and an insulating layer embedding the body line, where the body line is grounded.

In some embodiments, the semiconductor substrate and the body line are made of a same material.

In some embodiments, the semiconductor substrate and the body line are integrally formed into one piece.

In some embodiments, a conductivity of the body line is higher than a conductivity of the semiconductor substrate.

In some embodiments, a top surface of the body line is lower than or levelled with the top surface of the channel region.

In some embodiments, a bottom surface of the body line is levelled with the bottom surface of the channel region.

In some embodiments, the fin type word line physically contacts a second sidewall of the channel region opposite to or connected to the first sidewall.

In some embodiments, a sidewall of the body line extends beyond a second sidewall of the channel region connected to the first sidewall.

In some embodiments, a sidewall of the body line is levelled with a second sidewall of the channel region connected to the first sidewall.

In some embodiments, the body line and the fin type word line are separated by the insulating layer.

According to some embodiments of the present disclosure, a memory device includes a first memory cell. The first memory cell includes a first bit line, a first word line above the first bit line, and a first semiconductor substrate on the first bit line. The first word line includes a plurality of first fin type word lines, a first fin connector connecting the first fin type word lines, and a first common word line on the first fin connector. The first memory cell also includes a first body line physically contacting one of sidewalls of the first semiconductor substrate and an insulating layer embedding the first body line, where the first fin type word lines partially cover others of the sidewalls of the first semiconductor substrate.

In some embodiments, the first memory cell further includes a storage node contact covering a top surface of the first semiconductor substrate and a capacitor on the storage node contact, where a bottom surface of the first semiconductor substrate contacts the first bit line.

In some embodiments, the first body line is separated from the storage node contact.

In some embodiments, the storage node contact includes a polysilicon liner contacting the top surface of the first semiconductor substrate and a metal layer between the polysilicon liner and the capacitor.

In some embodiments, the first bit line and a group of the first fin type word lines extend along a first direction, and the first common word line, another group of the first fin type word lines, and the first body line extend along a second direction different from the first direction.

In some embodiments, the memory device further includes a second memory cell. The second memory cell includes a second bit line adjacent to the first bit line, the first word line above the second bit line, and a second semiconductor substrate on the second bit line, where the first word line includes a plurality of second fin type word lines and a second fin connector connecting the second fin type word lines and the first common word line. The second memory cell also includes the first body line physically contacting one of sidewalls of the second semiconductor substrate, where the second fin type word lines partially cover others of the sidewalls of the second semiconductor substrate. The first semiconductor substrate and the second semiconductor substrate are connected by the first body line.

In some embodiments, the memory device further includes a second memory cell. The second memory cell includes the first bit line, a second word line adjacent to the first body line and above the first bit line, and a second semiconductor substrate on the first bit line. The second word line includes a plurality of second fin type word lines, a second fin connector connecting the second fin type word lines, and a second common word line on the second fin connector. The second memory cell also includes a second body line physically contacting one of sidewalls of the second semiconductor substrate, where the second fin type word lines partially cover others of the sidewalls of the second semiconductor substrate.

In some embodiments, the memory device further includes a second memory cell including a second semiconductor substrate on a second bit line, where one of the sidewalls of the first semiconductor substrate and one of the sidewalls of the second semiconductor substrate are connected by the first body line. Others of the sidewalls of the second semiconductor substrate are partially covered by a plurality of second fin type word lines of the first word line. The memory device further includes a third memory cell including a third semiconductor substrate on the first bit line, where one of sidewalls of the third semiconductor substrate physically contacts a second body line, and others of the sidewalls of the third semiconductor substrate are partially covered by a plurality of third fin type word lines of a second word line. The memory device further includes a fourth memory cell comprising a fourth semiconductor substrate on the second bit line, where one of the sidewalls of the third semiconductor substrate and one of the sidewalls of the fourth semiconductor substrate are connected by the second body line. Others of the sidewalls of the fourth semiconductor substrate are partially covered by a plurality of fourth fin type word lines of the second word line.

In some embodiments, the memory device further includes a word line contact connected to the first common word line and a body line contact connecting the first body line and ground, where the word line contact and the body line contact are disposed on opposite sides of the first memory cell.

In some embodiments, the memory device further includes a word line contact connected to the first common word line and a body line contact connecting the first body line and ground, where the word line contact and the body line contact are disposed on a same side of the first memory cell.

According to the above mentioned embodiments, a memory device includes a memory cell including a bit line, a word line including fin type word lines and a fin connector connecting the fin type word lines, a semiconductor substrate with the sidewalls partially covered by the fin type word lines, a body line physically contacting one of the sidewalls of the semiconductor substrate, and an insulating layer embedding the body line, where the body line is grounded to reduce the floating body effect in the memory cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional schematic view of a memory device, according to one embodiment of the present disclosure.

FIG. 2 illustrates an enlarged top view of the memory device in FIG. 1.

FIG. 3 and FIG. 4 illustrate cross-sectional views of the memory device in FIG. 1.

FIG. 5 illustrates a cross-sectional view of a memory device, according to another embodiment of the present disclosure.

FIG. 6 illustrates a cross-sectional view of a memory device, according to another embodiment of the present disclosure.

FIG. 7 illustrates a cross-sectional view of a memory device, according to another embodiment of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some embodiments of the present disclosure, a memory device includes a memory cell including a bit line, a word line including fin type word lines, a semiconductor substrate on the bit line with sidewalls partially covered the fin type word lines, a body line physically contacting one of the sidewalls of the semiconductor substrate, and an insulating layer embedding the body line. The bit line, the fin type word lines, and the semiconductor substrate function as vertical fin-gate transistors in the memory cell, where the body line is grounded to reduce the floating body effect of the vertical fin-gate transistors.

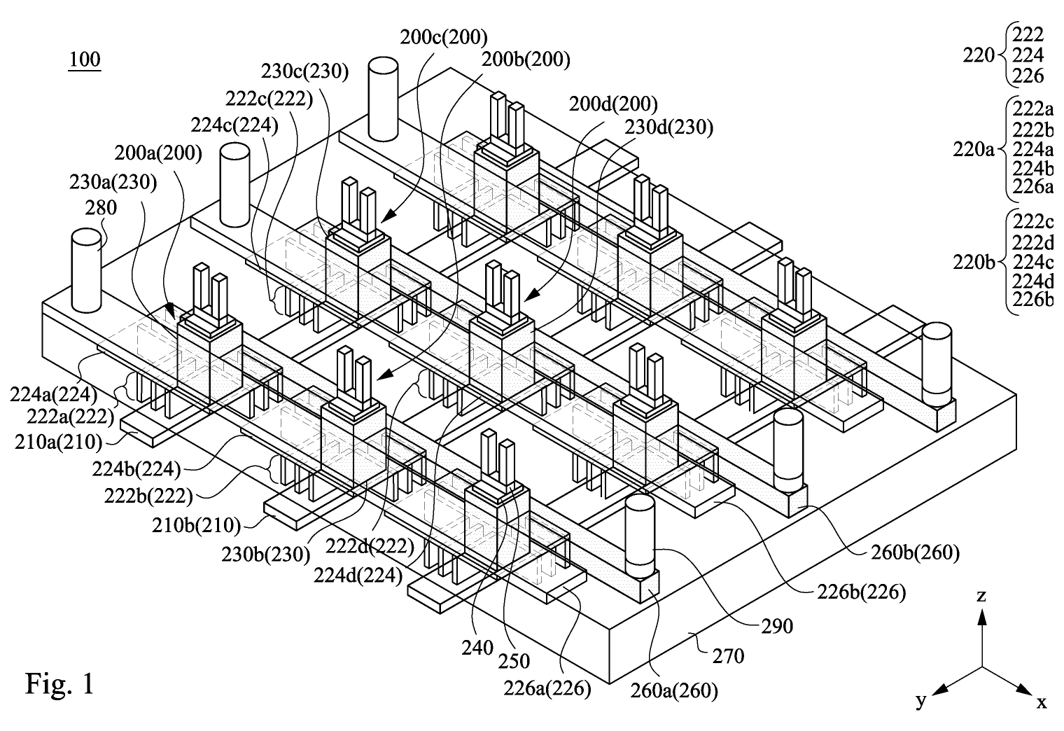

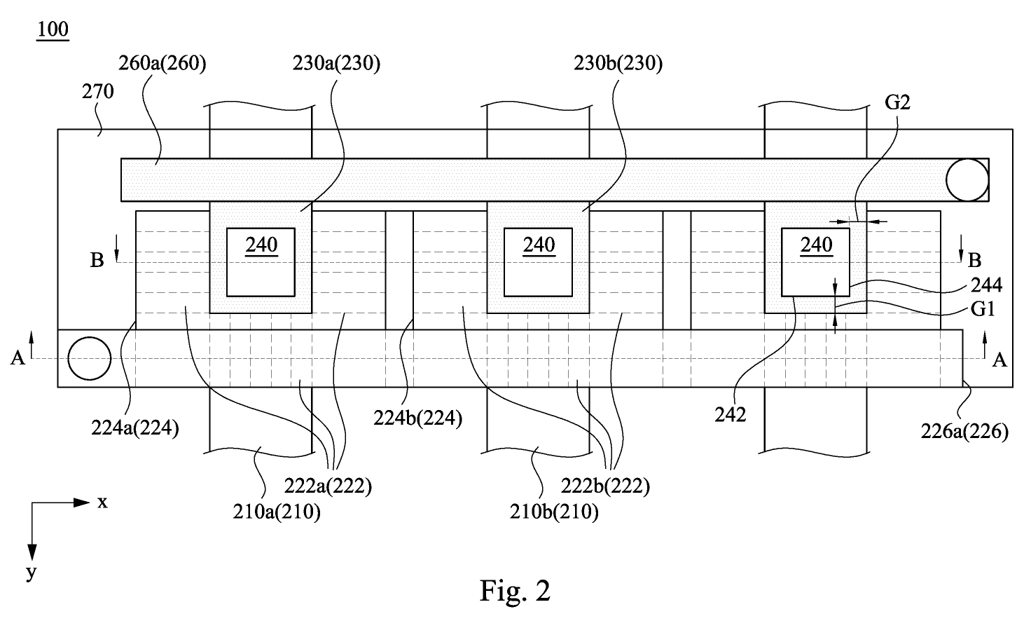

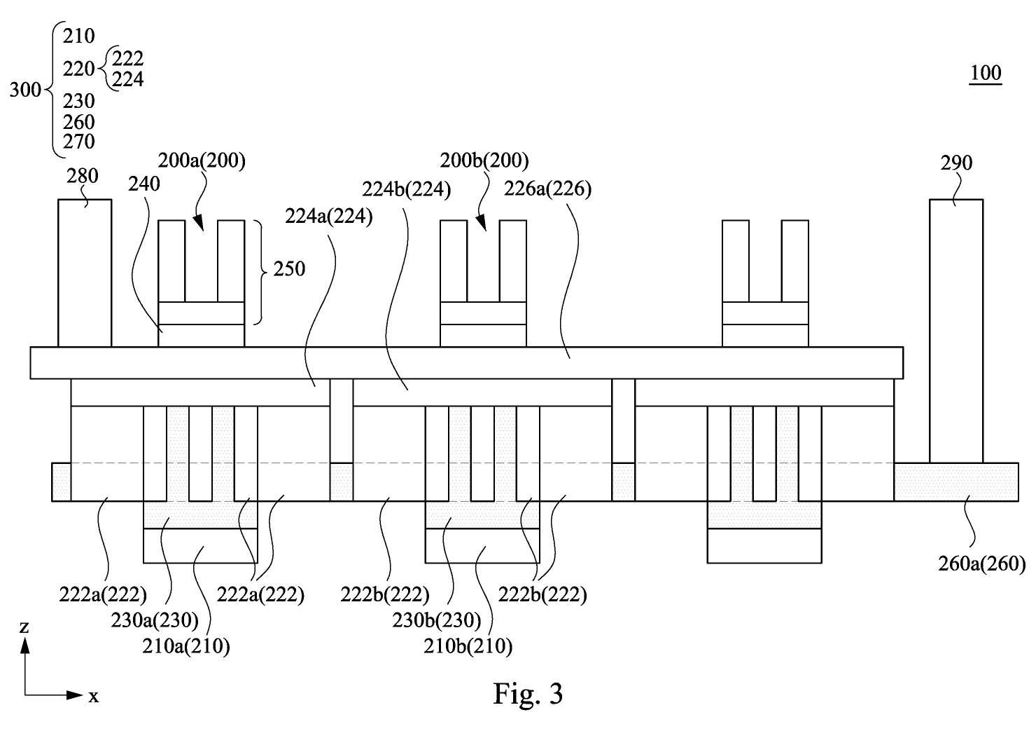

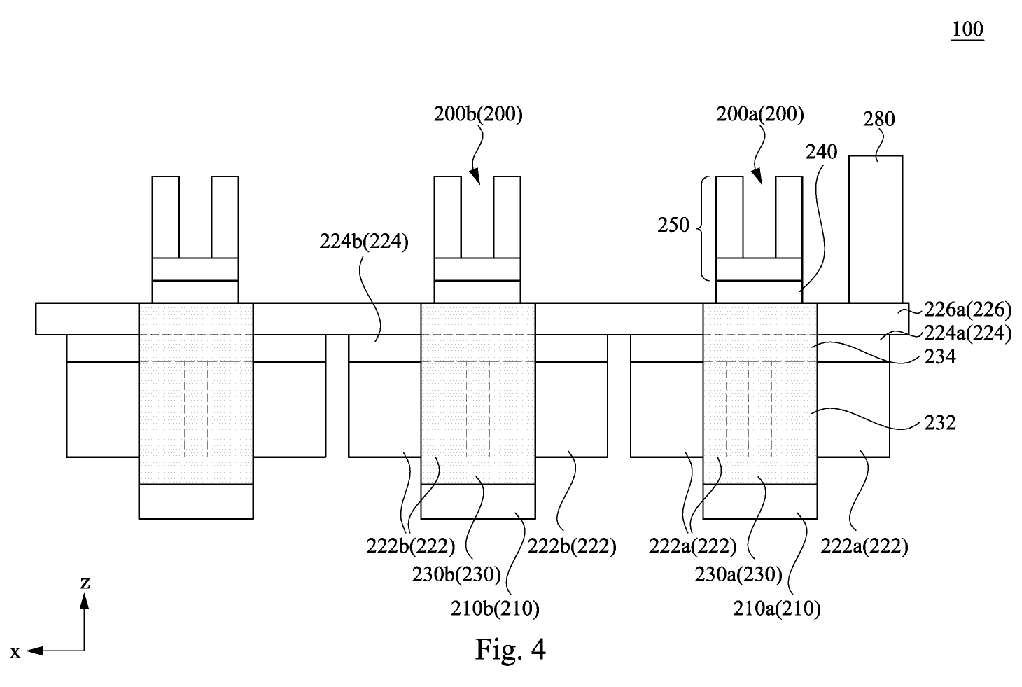

FIG. 1 illustrates a three-dimensional schematic view of a memory device 100, according to one embodiment of the present disclosure. The memory device 100 includes memory cells 200 arranged in a two-dimensional array. For the sake of simplicity, nine memory cells 200 are arranged in a 3×3 array for the memory device 100 illustrated in FIG. 1. However, no limitations on the number of memory cells 200 that may be included in the memory device 100 are intended. To clearly illustrate the details of the memory cells 200, FIG. 2 illustrates an enlarged top view of three memory cells 200 of the memory device 100 in FIG. 1; FIG. 3 illustrates a cross-sectional view of the memory device 100 along the line A-A′ in FIG. 2; and FIG. 4 illustrates a cross-sectional view of the memory device 100 along the line B-B′ in FIG. 2.

Referring to FIG. 1 to FIG. 4, a memory cell 200 includes a bit line 210, a word line 220 above the bit line 210, and a semiconductor substrate 230 on the bit line 210. The bit line 210 extends in the y-axis direction. The word line 220 includes a plurality of fin type word lines 222 separated from each other, a fin connector 224 on the top surfaces of the fin type word lines 222, and a common word line 226 on the top surface of the fin connector 224, where the common word line 226 applies a bias on to the fin type word lines 222 connected by the fin connector 224. The fin type word lines 222 are separated into groups that are respectively disposed on different sidewalls of the semiconductor substrate 230, where each group of the fin type word lines 222 extends in the y-axis direction or the x-axis direction. The fin connector 224 may include three portions, where the portion of the fin connector 224 extending in the y-axis direction is disposed on the fin type word lines 222 that extend in the x-axis direction, and the portion of the fin connector 224 extending in the x-axis direction is disposed on the fin type word lines 222 that extend in the y-axis direction. The common word line 226 extends in the x-axis direction. The word line 220 is separated from the bit line 210 along the z-axis direction.

The semiconductor substrate 230 are electrically connected to the bit line 210 and partially covered by the fin type word lines 222. For example, the bottom surface of the semiconductor substrate 230 may contact the top surface of the bit line 210, while three of the sidewalls of the semiconductor substrate 230 may be partially covered by the fin type word lines 222. As a result, the bit line 210, the fin type word lines 222, and the semiconductor substrate 230 may function as vertical fin-gate transistors 300 in the memory cell 200.

Specifically, for each fin type word line 222, a middle portion of the sidewall of the semiconductor substrate 230 is covered by the fin type word line 222. As the fin type word line 222 functions as the gate controlling the current in the semiconductor substrate 230, the middle portion of the semiconductor substrate 230 covered by the fin type word line 222 may be referred to as a channel region 232 of a transistor, which is called as the vertical fin-gate transistor 300 for the fin structure of the fin type word line 222. To clearly illustrate the channel region 232, the fin type word line 222, the fin connector 224, and the common word line 226 hidden by the semiconductor substrate 230 in FIG. 4 are illustrated as dashed lines. In some embodiments, the fin type word line 222 may physically contact the sidewall of the channel region 232, and the fin connector 224 and the common word line 226 may be distanced from the sidewall of the channel region 232.

In addition to the channel region 232, the semiconductor substrate 230 includes a top portion protruding above the fin type word line 222 along the z-axis direction, which becomes a top source/drain region 234 on the top surface of the channel region 232. The semiconductor substrate 230 also includes a bottom portion protruding below the fin type word line 222 along the z-axis direction, which becomes a bottom source/drain region 236 below the bottom surface of the channel region 232. Therefore, a semiconductor substrate 230 may function as the channel and the source/drain regions of a vertical fin-gate transistor 300.

In some embodiments, the semiconductor substrate 230 may have a suitable aspect ratio so that multiple sidewalls of the semiconductor substrate 230 are partially covered by the fin type word lines 222. Specifically, the semiconductor substrate 230 may have a first sidewall on the x-z plane covered by a group of the fin type word lines 222 and a second sidewall on the y-z plane covered by another group of the fin type word lines 222. The first width of the first sidewall is the same as or similar to the second width of the second sidewall. For example, a ratio of the first width to the second width may be in a range of 0.5:1 to 1.5:1. In such embodiments, the sidewalls of the semiconductor substrate 230 may be partially covered by a same number of the fin type word lines 222.

In some embodiments, the bit line 210, the word line 220, and the semiconductor substrate 230 may be made of suitable materials to form the vertical fin-gate transistors 300 in the memory cell 200. For example, the bit line 210 may include a conductive material, such as tungsten, copper, or other metal, buried in a substrate (not shown). The fin type word lines 222, the fin connector 224, and the common word line 226 may include a layer stack of oxides, polysilicon, high dielectric constant materials, metal gate materials, or combinations thereof. The semiconductor substrate 230 may include silicon, polysilicon, compound semiconductor, or other semiconductor material.

The memory cell 200 further includes a storage node contact 240 and a capacitor 250 above the semiconductor substrate 230 along the z-axis direction. The storage node contact 240 covers the top surface of the semiconductor substrate 230 so that the storage node contact 240 is connected to the top source/drain regions 234 of the vertical fin-gate transistors 300. The capacitor 250 is disposed on the top surface of the storage node contact 240. To clearly illustrate the arrangement of other elements in the memory cells 200, the capacitor 250 is omitted in FIG. 2.

As the semiconductor substrate 230 of one memory cell 200 is sandwiched between one bit line 210 and one capacitor 250, the middle portions of the semiconductor substrate 230 covered by the fin type word lines 222 of the memory cell 200 may be referred to as the channels regions 232 of the vertical fin-gate transistors 300 connected in parallel in the memory cell 200. In other words, the number of the fin type word lines 222 covering the sidewalls of one semiconductor substrate 230 corresponds to the number of vertical fin-gate transistors 300 in one memory cell 200. The multiple fin type word lines 222 in the memory cell 200 may reduce the critical dimension of the vertical fin-gate transistors 300, thereby improving the unit integration in the memory device 100. Since the fin width and the fin height of the fin type word lines 222 are related to the channel width and the channel length of the vertical fin-gate transistors 300, the thinned fin type word lines 222 in the memory cell 200 may also increase the driving-current of the vertical fin-gate transistors 300.

The sidewalls of the storage node contact 240 may be distanced from the sidewalls of the semiconductor substrate 230 to prevent the storage node contact 240 from physically contacting the word line 220. As shown in FIG. 2, the sidewall 242 of the storage node contact 240 faces a group of the fin type word lines 222. The sidewall 244, which is connected to the sidewall 242, of the storage node contact 240 faces another group of the fin type word lines 222. The sidewall 242 may be distanced from the closest sidewall of the semiconductor substrate 230 by a gap G1 in the y-axis direction, while the sidewall 242 may be distanced from the closest sidewall of the semiconductor substrate 230 by a gap G2 in the x-axis direction. In some embodiments, the width of the gap G1 may be the same or similar to the width of the gap G2.

In some embodiments, the storage node contact 240 may include a polysilicon liner near the semiconductor substrate 230 and a metal layer between the polysilicon liner and the capacitor 250 to reduce the junction leakage between the storage node contact 240 and the semiconductor substrate 230 and the contact resistance between the storage node contact 240 and the capacitor 250. For example, the storage node contact 240 may include a polysilicon liner contacting the top surface of the semiconductor substrate 230, a metal silicide layer on the polysilicon liner, and a metal layer on the metal silicide layer.

The memory cell 200 further includes a body line 260 extending in the x-axis direction adjacent to the word line 220. The body line 260 functions as a conductive path for the vertical fin-gate transistors 300 to release excess charges in the semiconductor substrate 230. Specifically, the body line 260 physically contacts a sidewall of the semiconductor substrate 230 opposite to the word line 220, particularly the sidewall of the channel regions 232 of the semiconductor substrate 230. In other words, the channel regions 232 in the semiconductor substrate 230 in the memory cell 200 are connected together by the body line 260. When the charges are accumulated in the channel regions 232 during the operation of the vertical fin-gate transistors 300, the body line 260 is grounded to direct the accumulated charges out of the channel regions 232, thereby reducing the floating body effect of the vertical fin-gate transistors 300.

In some embodiments, the memory cell 200 may further include an insulating layer 270 embedding the body line 260. Since the body line 260 is embedded in the insulating layer 270, the body line 260 may be referred to as “buried body line”. In addition, the insulating layer 270 may interpose between the sidewalls of the fin type word lines 222 to separate the fin type word lines 222 from each other. The insulating layer 270 may also interpose between the bottom surfaces of the fin type word lines 222 and the top surface of the bit line 210 to separate the fin type word lines 222 from the bit line 210. It should be noted that the insulating layer 270 is omitted in the cross-sectional views, such as FIG. 3 and FIG. 4, to clearly illustrate the arrangement of other elements in the memory cells 200.

In some embodiments, the body line 260 and the semiconductor substrate 230 may be made of a same material, such as silicon or polysilicon, to increase the charge releasing efficiency of the body line 260. The body line 260 and the semiconductor substrate 230 having the same material may be formed simultaneously, which simplifies the manufacturing process of the memory cell 200. In such embodiments, the body line 260 and the semiconductor substrate 230 may be integrally formed into one piece to reduce the interfaces between the body line 260 and the semiconductor substrate 230, which improves the charge releasing efficiency and the structure strength.

In some other embodiments, the body line 260 and the semiconductor substrate 230 may include different materials, where a conductivity of the body line 260 is higher than a conductivity of the semiconductor substrate 230. The conductivity difference between the body line 260 and the semiconductor substrate 230 may increase the charge releasing efficiency of the body line 260. For example, the semiconductor substrate 230 may be made of silicon, while the body line 260 may be made of metal.

In some embodiments, the body line 260 and the fin type word lines 222 may be separated by the insulating layer 270, such that the body line 260 directs the charges out of the semiconductor substrate 230 rather than the word line 220. For example, one sidewall of the semiconductor substrate 230 may physically contact the body line 260, and all other sidewalls of the semiconductor substrate 230 are partially covered by the fin type word lines 222. The insulating layer 270 is interposed between the body line 260 and the fin type word line 222 closest to the body line 260, and the fin type word line 222 closest to the body line 260 may physically contact the insulating layer 270.

In some embodiments, the bottom surface of the body line 260 may be levelled with the bottom surfaces of the channel regions 232. As shown in FIG. 3, the top surface and the bottom surface of the body line 260 hidden by the semiconductor substrate 230 are illustrated as dashed lines, where the bottom surface of the body line 260 is levelled with the bottom surfaces of the channel regions 232 (as shown in FIG. 4). In other words, the bottom surface of the body line 260 may be levelled with the bottom surfaces of the fin type word lines 222. As a result, the body line 260 is separated from the bit line 210 to direct the charges out of the semiconductor substrate 230 rather than the bit line 210.

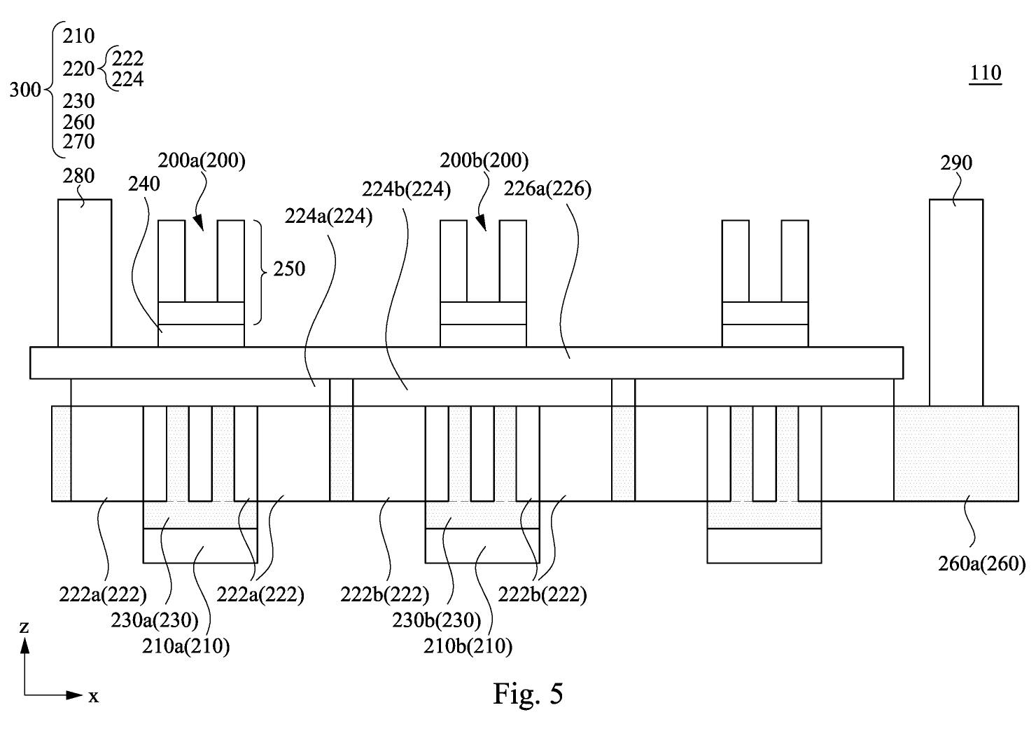

In addition, the top surface of the body line 260 may be levelled with or lower than the top surfaces of the channel regions 232. In other words, the top surface of the body line 260 may be levelled with or lower than the top surface of the fin type word lines 222. As a result, the body line 260 is separated from the storage node contact 240 to direct the charges out of the semiconductor substrate 230 rather than the storage node contact 240. The memory device 100 in FIG. 3 shows the body line 260 having the top surface lower than the top surfaces of the channel regions 232 (as shown in FIG. 4). According to another embodiment of the present disclosure, FIG. 5 illustrates a cross-sectional view of a memory device 110. The memory device 110 is similar to the memory device 100 in FIG. 3, except for the body line 260 having the top surface levelled with the top surfaces of the channel regions 232 (as shown in FIG. 4).

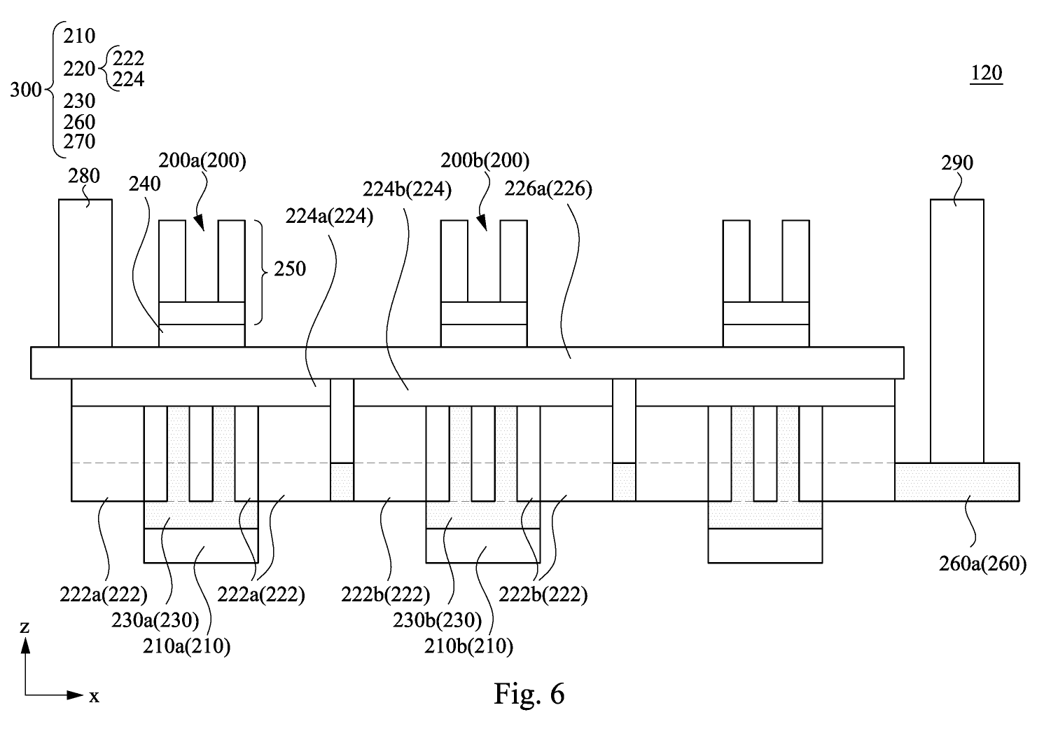

In some embodiments, a sidewall of the body line 260 may extend beyond or be levelled with a sidewall of the channel regions 232 closest to the edge of the two-dimensional array of the memory cells 200. In such embodiments, each of the channel regions 232 has a sidewall fully covered by the body line 260 to increase the charge releasing efficiency of the body line 260. The memory device 100 in FIG. 3 shows the body line 260 having the sidewall extending beyond the sidewall of the channel region 232 (as shown in FIG. 4) closest to the edge of the two-dimensional array. According to another embodiment of the present disclosure, FIG. 6 illustrates a cross-sectional view of a memory device 120. The memory device 120 is similar to the memory device 100 in FIG. 3, except for the body line 260 having the sidewall levelled with the sidewall of the channel region 232 (as shown in FIG. 4) closest to the edge of the two-dimensional array.

As mentioned above, a vertical fin-gate transistor 300 includes a bit line 210, a word line 220 including a fin type word line 222, a fin connector 224, and a common word line 226, a semiconductor substrate 230 on the bit line 210 and partially covered by the fin type word line 222, a body line 260 physically contacting the semiconductor substrate 230, and an insulating layer 270 embedding the body line 260. A memory cell 200 includes multiple vertical fin-gate transistors 300, where the channel regions of the vertical fin-gate transistors 300 are connected by the body line 260. A memory device 100 includes multiple memory cells 200, where the memory cells 200 are connected by the body line 260 or the bit line 210 to form the two-dimensional array.

For example, as shown in FIG. 1, the memory device 100 includes a first memory cell 200a, a second memory cell 200b, a third memory cell 200c, and a fourth memory cell 200d. The first memory cell 200a includes the bit line 210a, the word line 220a including the fin type word lines 222a, the fin connector 224a, and the common word line 226a, the semiconductor substrate 230a on the bit line 210a, and the body line 260a physically contacting one of the sidewalls of the semiconductor substrate 230a, where the other sidewalls of the semiconductor substrate 230a are partially covered by the fin type word lines 222a. The second memory cell 200b includes the bit line 210b adjacent to the bit line 210a, the word line 220a including the fin type word lines 222b, the fin connector 224b, and the common word line 226a, the semiconductor substrate 230b on the bit line 210b, and the body line 260a physically contacting one of the sidewalls of the semiconductor substrate 230b, where the other sidewalls of the semiconductor substrate 230b are partially covered by the fin type word lines 222b.

Similarly, the third memory cell 200c includes the bit line 210a, the word line 220b including the fin type word lines 222c, the fin connector 224c, and the common word line 226b, the semiconductor substrate 230c on the bit line 210a, and the body line 260b physically contacting one of the sidewalls of the semiconductor substrate 230c, where the other sidewalls of the semiconductor substrate 230c are partially covered by the fin type word lines 222c. The word lines 220a and 220b and the body lines 260a and 260b are alternately arranged. The fourth memory cell 200d includes the bit line 210b, the word line 220b including the fin type word lines 222d, the fin connector 224d, and the common word line 226b, the semiconductor substrate 230d on the bit line 210b, and the body line 260b physically contacting one of the sidewalls of the semiconductor substrate 230d, where the other sidewalls of the semiconductor substrate 230d are partially covered by the fin type word lines 222d.

The semiconductor substrate 230a and the semiconductor substrate 230b are connected by the body line 260a, the semiconductor substrate 230a and the semiconductor substrate 230c are connected by the bit line 210a, and the semiconductor substrate 230c and the semiconductor substrate 230d are connected by the body line 260b. As a result, the first memory cell 200a to the fourth memory cell 200d are arranged in a 2×2 array for the memory device 100. In some embodiments, the first memory cell 200a to the fourth memory cell 200d may be repeatedly arranged to form a 4F2 structure of a dynamic random access memory (DRAM).

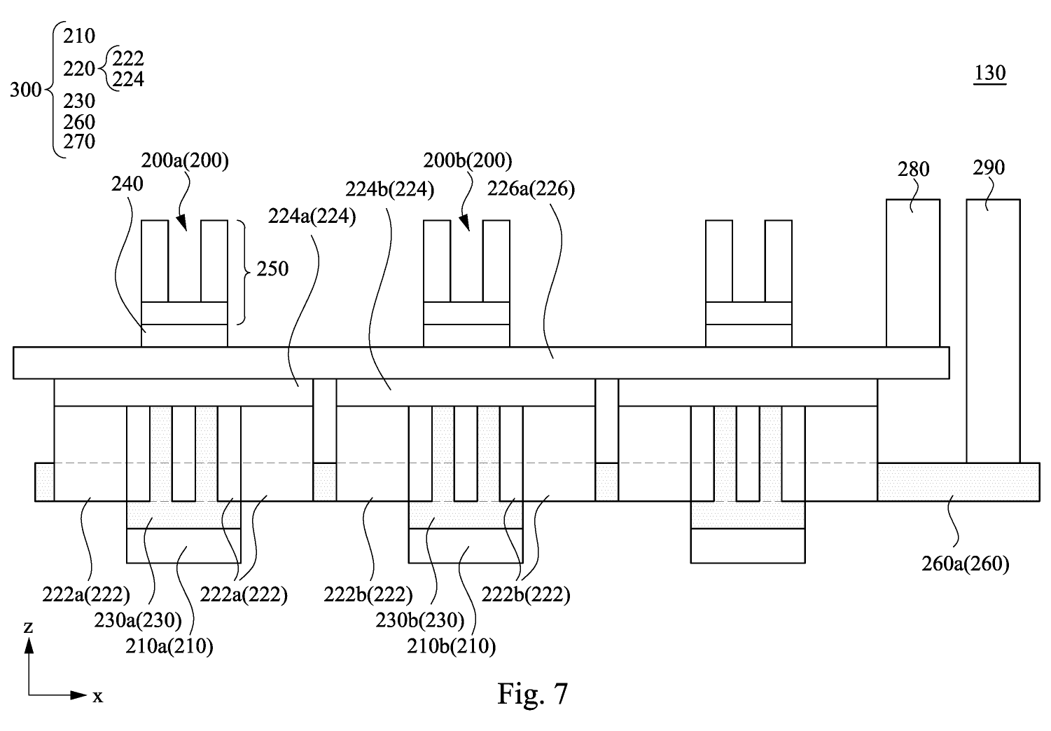

In some embodiment, the memory device 100 may further include a word line contact 280 connected to the common word line 226 to apply bias onto the word line 220. The memory device 100 may also include a body line contact 290 connecting the body line 260 and ground to direct the charges out of the body line 260. The word line contact 280 and the body line contact 290 may be disposed on the opposite sides or the same side of a memory cell 200. The memory device 100 in FIG. 3 shows the word line contact 280 and the body line contact 290 on the opposite sides of the memory cell 200. According to another embodiment of the present disclosure, FIG. 7 illustrates a cross-sectional view of a memory device 130. The memory device 130 is similar to the memory device 100 in FIG. 3, except for the word line contact 280 and the body line contact 290 on the same side of the memory cell 200.

According to the above mentioned embodiments, the memory device of the present disclosure includes the memory cells, where each of the memory cells includes the bit line, the word line including the fin type word lines, the fin connector, and the common word line, the semiconductor substrate on the bit line with some sidewalls partially covered by the fin type word lines, the body line physically contacting the other sidewall of the semiconductor substrate, and the insulating layer embedding the body line. The bit line, the fin type word lines, and the semiconductor substrate may function as vertical fin-gate transistors connected in parallel in the memory cell, thereby improving the unit integration in the memory device. The body line is grounded to direct the accumulated charges out of the semiconductor substrate, which reduces the floating body effect of the vertical fin-gate transistors in the memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A vertical fin-gate transistor, comprising:
a bit line;
a word line above the bit line, comprising:
a fin type word line;
a fin connector on a top surface of the fin type word line; and
a common word line on a top surface of the fin connector;
a semiconductor substrate on the bit line, comprising:
a channel region covered by the fin type word line;
a top source/drain region on a top surface of the channel region; and
a bottom source/drain region below a bottom surface of the channel region,
wherein a ratio of widths of sidewalls of the semiconductor substrate is in a range of 0.5:1 to 1.5:1;
a body line physically contacting a first sidewall of the channel region, wherein the body line is grounded; and
an insulating layer embedding the body line.

2. The vertical fin-gate transistor of claim 1, wherein the semiconductor substrate and the body line are made of a same material.

3. The vertical fin-gate transistor of claim 1, wherein the semiconductor substrate and the body line are integrally formed into one piece.

4. The vertical fin-gate transistor of claim 1, wherein a conductivity of the body line is higher than a conductivity of the semiconductor substrate.

5. The vertical fin-gate transistor of claim 1, wherein a top surface of the body line is lower than or levelled with the top surface of the channel region.

6. The vertical fin-gate transistor of claim 1, wherein a bottom surface of the body line is levelled with the bottom surface of the channel region.

7. The vertical fin-gate transistor of claim 1, wherein the fin type word line physically contacts a second sidewall of the channel region opposite to or connected to the first sidewall.

8. The vertical fin-gate transistor of claim 1, wherein a sidewall of the body line extends beyond a second sidewall of the channel region connected to the first sidewall.

9. The vertical fin-gate transistor of claim 1, wherein a sidewall of the body line is levelled with a second sidewall of the channel region connected to the first sidewall.

10. The vertical fin-gate transistor of claim 1, wherein the body line and the fin type word line are separated by the insulating layer.

11. A memory device, comprising:
a first memory cell, comprising:
a first bit line;
a first word line above the first bit line, wherein the first word line comprises a plurality of first fin type word lines, a first fin connector connecting the first fin type word lines, and a first common word line on the first fin connector;
a first semiconductor substrate on the first bit line;
a first body line physically contacting one of sidewalls of the first semiconductor substrate, wherein the first fin type word lines partially cover others of the sidewalls of the first semiconductor substrate; and
an insulating layer embedding the first body line.

12. The memory device of claim 11, wherein the first memory cell further comprises:
a storage node contact covering a top surface of the first semiconductor substrate, wherein a bottom surface of the first semiconductor substrate contacts the first bit line; and
a capacitor on the storage node contact.

13. The memory device of claim 12, wherein the first body line is separated from the storage node contact.

14. The memory device of claim 12, wherein the storage node contact comprises:
a polysilicon liner contacting the top surface of the first semiconductor substrate; and
a metal layer between the polysilicon liner and the capacitor.

15. The memory device of claim 11, wherein the first bit line and a group of the first fin type word lines extend along a first direction, and wherein the first common word line, another group of the first fin type word lines, and the first body line extend along a second direction different from the first direction.

16. The memory device of claim 11, further comprising:
a second memory cell, comprising:
a second bit line adjacent to the first bit line;
the first word line above the second bit line, comprising a plurality of second fin type word lines and a second fin connector connecting the second fin type word lines and the first common word line;
a second semiconductor substrate on the second bit line; and
the first body line physically contacting one of sidewalls of the second semiconductor substrate, wherein the second fin type word lines partially cover others of the sidewalls of the second semiconductor substrate,
wherein the first semiconductor substrate and the second semiconductor substrate are connected by the first body line.

17. The memory device of claim 11, further comprising:
a second memory cell, comprising:
the first bit line;
a second word line adjacent to the first body line and above the first bit line, wherein the second word line comprises a plurality of second fin type word lines, a second fin connector connecting the second fin type word lines, and a second common word line on the second fin connector;
a second semiconductor substrate on the first bit line; and
a second body line physically contacting one of sidewalls of the second semiconductor substrate, where the second fin type word lines partially cover others of the sidewalls of the second semiconductor substrate.

18. The memory device of claim 11, further comprising:
a second memory cell comprising a second semiconductor substrate on a second bit line, wherein the one of the sidewalls of the first semiconductor substrate and one of the sidewalls of the second semiconductor substrate are connected by the first body line, and wherein others of the sidewalls of the second semiconductor substrate are partially covered by a plurality of second fin type word lines of the first word line;
a third memory cell comprising a third semiconductor substrate on the first bit line, wherein one of sidewalls of the third semiconductor substrate physically contacting a second body line, others of the sidewalls of the third semiconductor substrate are partially covered by a plurality of third fin type word lines of a second word line; and
a fourth memory cell comprising a fourth semiconductor substrate on the second bit line, wherein the one of the sidewalls of the third semiconductor substrate and one of sidewalls of the fourth semiconductor substrate are connected by the second body line, and wherein others of the sidewalls of the fourth semiconductor substrate are partially covered by a plurality of fourth fin type word lines of the second word line.

19. The memory device of claim 11, further comprising:
a word line contact connected to the first common word line; and
a body line contact connecting the first body line and ground, wherein the word line contact and the body line contact are disposed on opposite sides of the first memory cell.

20. The memory device of claim 11, further comprising:
a word line contact connected to the first common word line; and
a body line contact connecting the first body line and ground, wherein the word line contact and the body line contact are disposed on a same side of the first memory cell.
